(19) United States
(12) Patent Application Publication
(10) Pub. No.: US 2023/0164919 A1
(43) Pub. Date: May 25, 2023

(54) CIRCUIT BOARD ASSEMLY AND METHOD FOR MANUFACTURING THE SAME

(71) Applicants: QING DING PRECISION ELECTRONICS (HUAIAN) CO.,LTD, Huai an (CN); Avary Holding (Shenzhen) Co., Limited., Shenzhen (CN)

(72) Inventor: SHI-JIE ZHONG, Shenzhen (CN)

(21) Appl. No.: 18/094,506

(22) Filed: Jan. 9, 2023

Related U.S. Application Data
(63) Continuation-in-part of application No. PCT/CN2021/101044, filed on Jun. 18, 2021.

(51) Int. Cl. H05K 1/14; H05K 1/11; H05K 3/36

(52) U.S. Cl. CPC H05K 1/147; H05K 1/119; H05K 3/36; H05K 2201/09063; H05K 2201/091

(57) ABSTRACT

A circuit board assembly includes a first circuit board and a second circuit board. The first circuit board includes a first contact pad and defines a stamped protrusion being correspondingly positioned relative to a position of the first contact pad, the first contact pad being outside the stamped protrusion. The second circuit board includes a second contact pad. The first contact pad on the stamping protrusion is in contact with the second contact pad to achieve electronic connections between the first circuit board and the second circuit board. A method for manufacturing the circuit board assembly is further disclosed.

### FIELD

The subject matter herein generally relates to circuit boards, in particular, to a circuit board assembly formed by connecting a plurality of circuit boards and a method for manufacturing the circuit board assembly.

### BACKGROUND

Functions of electronic products are always increasing, which leads to the number of circuit boards in the electronic products being increased. These circuit boards need to be electrically connected. The circuit boards are generally connected through a hot bar process. However, the hot bar process includes a reflow soldering process which process is complicated.

### BRIEF DESCRIPTION OF THE DRAWINGS

Implementations of the present technology will now be described, by way of embodiment, with reference to the attached figures.

FIG. 1 is a cross-sectional view of a double-sided copper clad laminate according to an embodiment of the present disclosure.

FIG. 2 is a cross-sectional view showing a through hole formed on the double-sided copper clad laminate of FIG. 1.

FIG. 3 is a cross-sectional view showing a conductive structure formed in the through hole of FIG. 2.

FIG. 4 is a cross-sectional view showing conductive wiring layers formed on the double-sided copper clad laminate of FIG. 3 as a first circuit board.

FIG. 5 is a bottom view of the first circuit board of FIG. 4.

FIG. 6 is a cross-sectional view showing protective layers formed on the conductive wiring layers of FIG. 4.

FIG. 7 is a bottom view of the first circuit board in FIG. 6.

FIG. 8 is a bottom view showing the first circuit board of FIG. 7 having a preset shape.

FIG. 9 is a bottom view showing slits formed between first contact pads of the first circuit board of FIG. 8.

FIG. 10 is a cross-sectional view showing stamped protrusions formed on the first circuit board of FIG. 9.

FIG. 11 is a cross-sectional view showing a supporting block arranged on the first circuit board of FIG. 10.

FIG. 12 is a bottom view of the first circuit board in FIG. 11.

FIG. 13 is a cross-sectional view of a second circuit board according to an embodiment of the present disclosure.

FIG. 14 is a bottom view of the second circuit board of FIG. 13.

FIG. 15 is a cross-sectional view showing two first circuit boards attached to opposite surfaces of the second circuit board.

FIG. 16 is a cross-sectional view showing an encapsulation layer formed on the first circuit boards of FIG. 15 and the second circuit board of FIG. 15.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

A method for manufacturing a circuit board assembly according to an embodiment includes steps as follows.

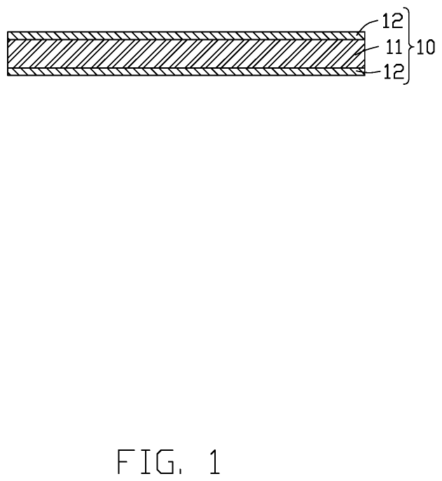

Step S1, referring to FIG. 1, a copper clad laminate 10 is provided. The copper clad laminate 10 includes a first insulating layer 11 and a copper layer 12 arranged on the first insulating layer 11. In this embodiment, the copper clad laminate 10 includes two copper layers 12 which are arranged on opposite surfaces of the first insulating layer 11. In other embodiments, the copper clad laminate 10 includes only one copper layer 12.

The first insulating layer 11 is made of a flexible insulating material, which is selected from a group consisting of liquid crystal polymer (LCP), poly tetra fluoro ethylene (PTFE), poly ether ether ketone (PEEK), polyphenylene oxide (PPO), polyimide (PI), polyethylene terephthalate (PET), polyethylene naphthalate (PEN), polyethylene (PE), and any combination thereof.

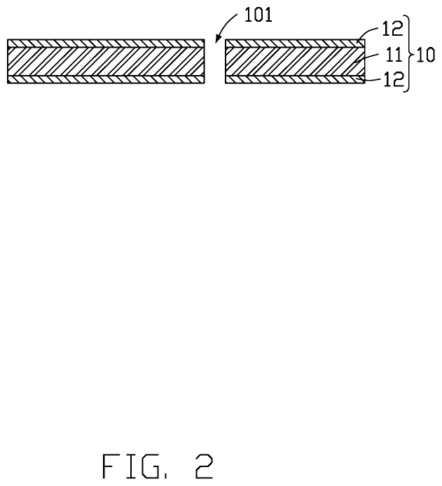

Step S2, referring to FIG. 2, a through hole 101 is formed on the copper clad laminate 10. The through hole 101 penetrates the first insulating layer 11 and the copper layers 12. In some embodiments, the through hole 101 is formed by mechanical drilling or laser drilling.

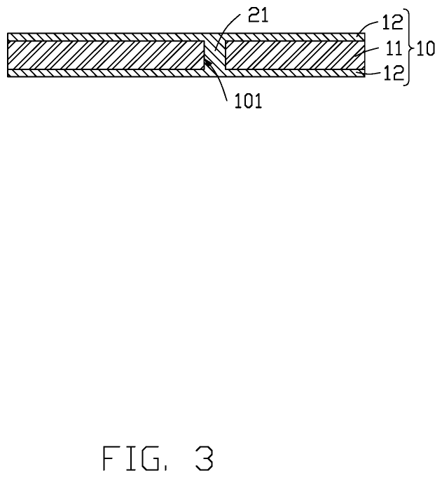

Step S3, referring to FIG. 3, a first conductive structure 21 is formed in the through hole 101. The first conductive structure 21 is coupled to the two copper layers 12.

In this embodiment, a coating is formed on a wall of the through hole 101, through an electroplating process, to obtain the first conductive structure 21. It can be understood that when the first conductive structure 21 is formed by electroplating, the coating is also formed on surfaces of the copper layers 12 facing away from the first insulating layer 11. In other embodiments, the first conductive structure 21 is formed by filling the through hole 101 with conductive materials.

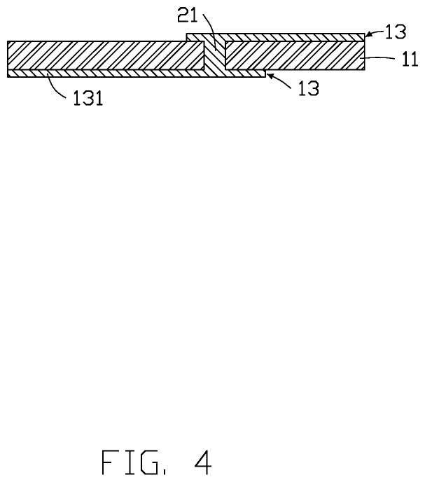

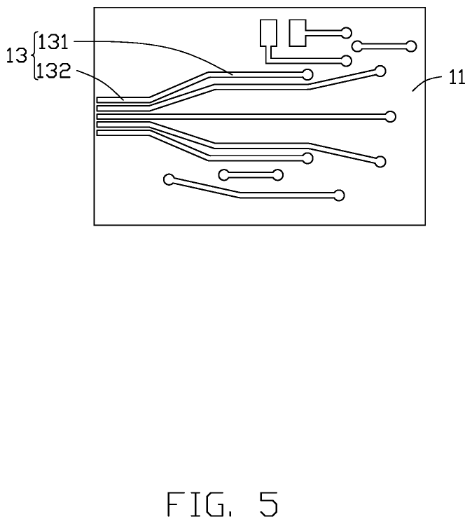

Step S3, referring to FIG. 4 and FIG. 5, the two copper layers 12 are processed to form two first conductive wiring layers 13. In some embodiments, the copper layers 12 are processed using a lithography process. The two first conductive wiring layers 13 are coupled through the first conductive structure 21.

One of the first conductive wiring layers 13 includes a plurality of lines 131 and a plurality of first contact pads 132. The first contact pads 132 are coupled to the lines 131, respectively. The first contact pads 132 are adjacent to an end of the first insulating layer 11 and are parallel with each other.

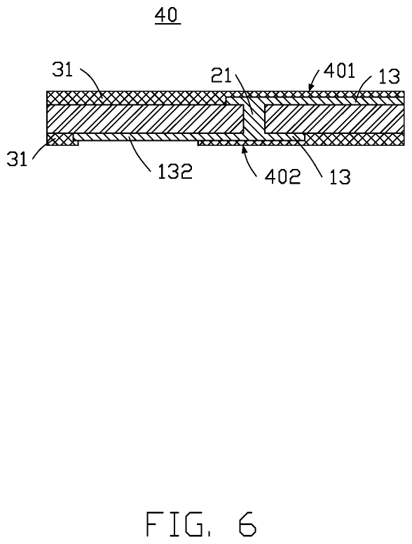

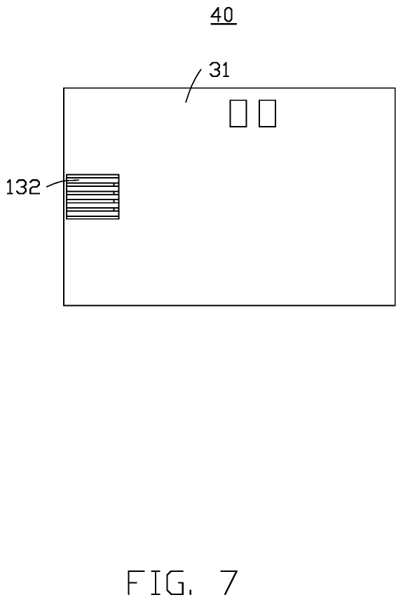

Step S4, referring to FIG. 6 and FIG. 7, two first protective layers 31 are formed on surfaces of the first conductive wiring layers 13 facing away from the first insulating layer 11, obtaining a first circuit board 40. The first contact pads 132 are exposed from a first protective layer 31.

The first protective layers 31 are configured to protect the first conductive wiring layers 13. The first protective layers 31 are cover films which are bonded to the first conductive wiring layers 13 or printed ink layers formed on the first conductive wiring layers 13.

The first circuit board 40 includes a first surface 401 with the first contact pads 132 and a second surface 402 opposite to the first surface 401. The two first protective layers 31 are respectively located on the first surface 401 and the second surface 402.

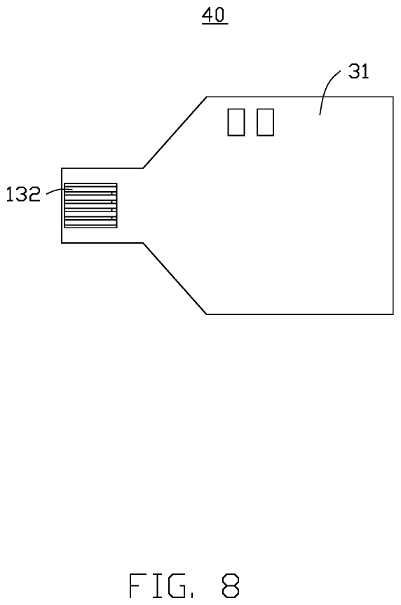

Step S5, referring to FIG. 8, an outline of the first circuit board 40 is cut to remove extra and excess materials, obtaining the circuit board 40 having a preset shape.

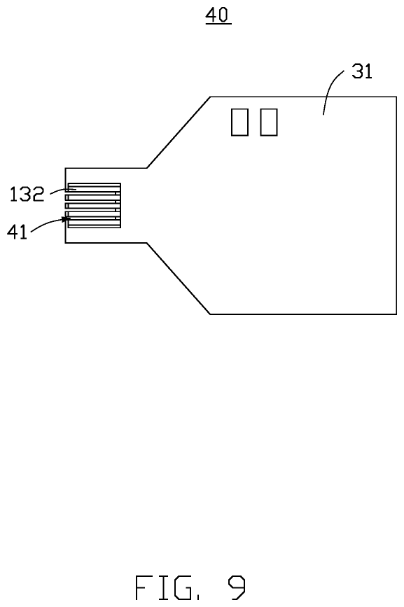

Step S6, referring to FIG. 9, a portion of the first circuit board 40 between any two adjacent first contact pads 132 is cut to form a slit 41 which penetrates an end of the first circuit board 40, to separate the first circuit board 40 into a plurality of portions. Each of the plurality of portions has one first contact pad 132. The separated portions of the first circuit board 40 having the first contact pads 132 are independent of each other and can be processed separately without interference.

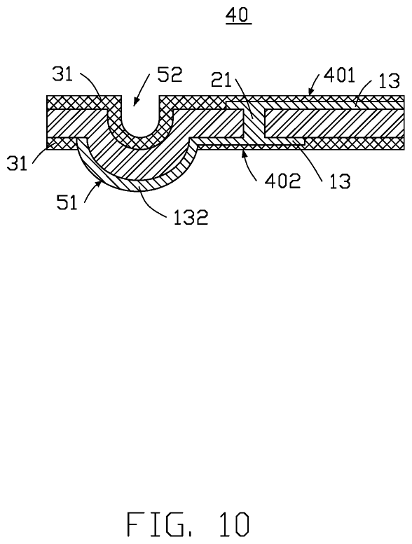

Step S7, referring to FIG. 10, the portions of the first circuit board 40 with the first contact pads 132 are stamped along a direction from the second surface 402 to the first surface 401, to form a plurality of stamped protrusions 51 being correspondingly positioned relative to positions of the first contact pads 132. Each first contact pad 132 is outside a stamped protrusion 51.

The stamped protrusions 51 protrude out of the first surface 401. A plurality of stamped grooves 52 are formed on the second surface 402, the stamped groove 52 corresponding in position to the stamped protrusions 51. Each stamped groove 52 has a shape matching that of a corresponding stamped protrusion 51. In this embodiment, a cross section of each stamped protrusion 51 is arc-shaped. In other embodiments, the cross section of each stamped protrusion 51 can be triangular, rectangular, trapezoidal, etc. It can be understood, each stamped protrusion 51 and the corresponding stamped groove 52 are formed simultaneously during a stamping process.

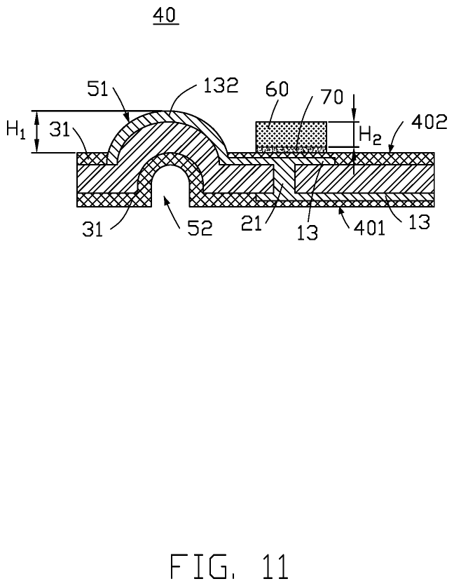

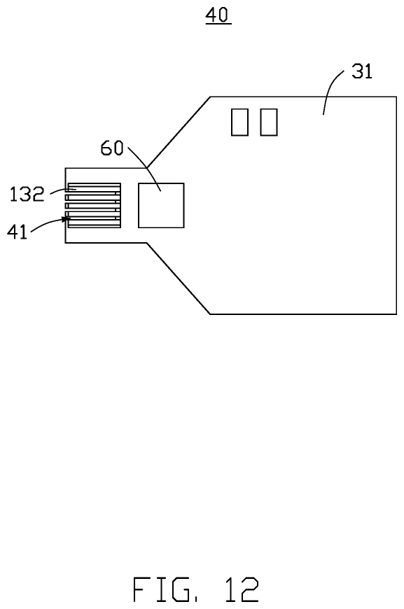

Step S8, referring to FIG. 11 and FIG. 12, a supporting block 60 is fixed on the first surface of the first circuit board 40. Specifically, the supporting block 60 is arranged on one first protective layer 13. The supporting block 60 is adjacent to the stamped protrusions 51. A height H₁ of each stamped protrusion 51 is greater than a height H₂ of the supporting block 60.

In some embodiments, an adhesive layer 70 is sandwiched between the supporting block 60 and the first circuit board 40, the supporting block 60 is bonded to the first circuit board 40 through the adhesive layer 70.

The adhesive layer 70 may include a viscous resin. The viscous resin may be at least one of polypropylene, epoxy, polyurethane, phenolic, urea-formaldehyde, melamine-formaldehyde and polyimide.

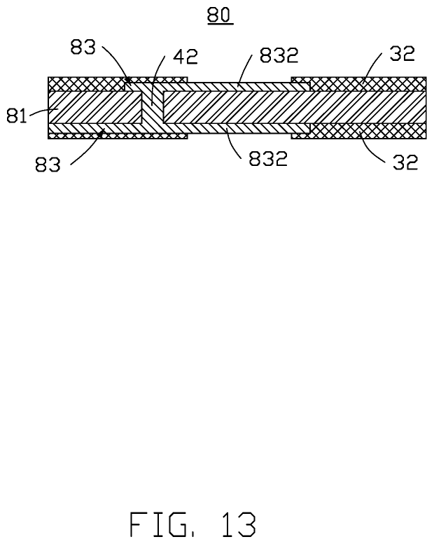

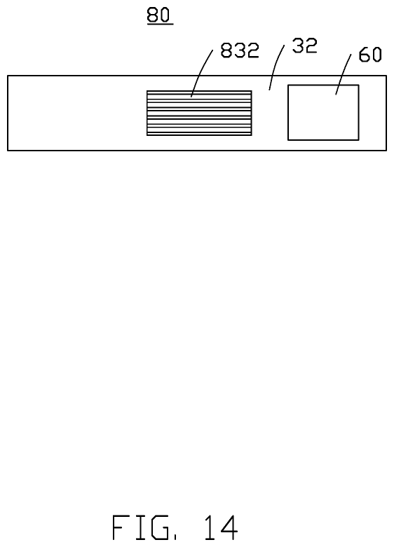

Step S9, referring to FIGS. 13 and 14, a second circuit board 80 is provided. The second circuit board 80 includes a second insulating layer 81 and a second conductive wiring layer 83 arranged on the second insulating layer 81. The second conductive wiring layer 83 includes a plurality of second contact pads 832. The second contact pads 832 are parallel to each other.

In this embodiment, the second circuit board 80 includes two second conductive wiring layers 83 which are arranged on opposite surfaces of the second insulating layers 81. The two second conductive wiring layers 83 are electrically connected with each other through a second conductive structure 42 which penetrates the second insulating layer 81. The second conductive structure 42 is a hole which is metallized or a conductive column. In other embodiment, the second circuit board 80 can include only one second conductive wiring layer 83.

The second circuit board 80 further includes two second protective layers 32. The second protective layers 32 cover surfaces of the second conductive wiring layers 83 facing away from the second insulating layer 81. The second contact pads 832 of one second conductive wiring layer 83 are exposed from a corresponding second protective layer 32. The second protective layers 32 are cover films or can be layers of ink.

The second insulating layer 81 is rigid. The second insulating layer 81 can be made of a resin material containing glass fibers.

In some embodiment, another supporting block 60 is arranged on the second protective layer 32 of the second circuit board 80. The supporting block 60 on the second circuit board 80 is configured to connect to the supporting block 60 on the first circuit board 40. In other embodiments, there is only one supporting block 60 arranged between the first circuit board 40 and the second circuit board 80.

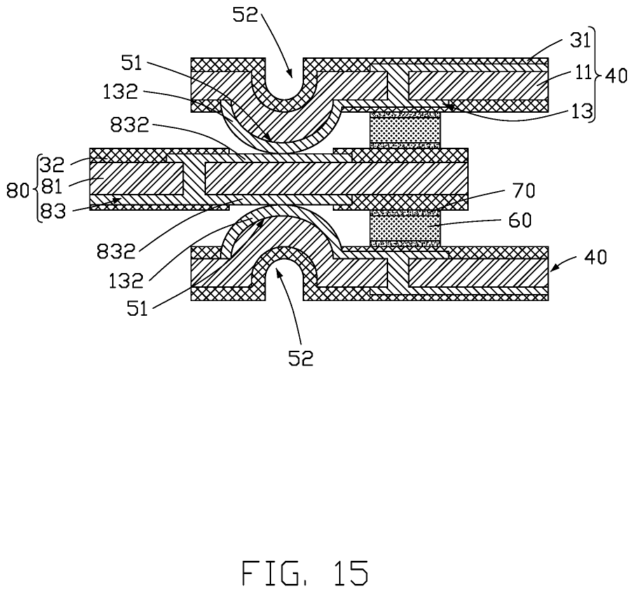

Step S10, referring to FIG. 15, the first circuit board 10 is pressed onto the second circuit board 80, each first contact pad 132 of one stamped protrusion 51 coming into contact with a corresponding second contact pad 832.

The supporting block 60 is sandwiched between the first circuit board 40 and the second circuit board 80. Since the height of the stamped protrusion 51 is greater than the height of the supporting block 60, the stamped protrusion 51 will deform under pressure and its height will be reduced when the first circuit board 40 is pressed onto the second circuit board 80, thereby the supporting block 60 can make contact with the second circuit board 80, and an area of contact between the first contact pad 132 and the corresponding second contact pad 832 is thus increased The first contact pad 132 is thus in close contact with the corresponding second contact pad 832 to maintain good conductivity.

In some embodiments, another adhesive layer 70 is sandwiched between the supporting block 60 and the second circuit board 80. The supporting block 60 is bonded to the second circuit board 80 through the adhesive layer 70.

In this embodiment, two first circuit boards 40 are pressed on opposite surfaces of the second circuit board 80, the stamped protrusions 51 of one first circuit board 40 are in contact with the second contact pads 832 of a corresponding second conductive wiring layer 83.

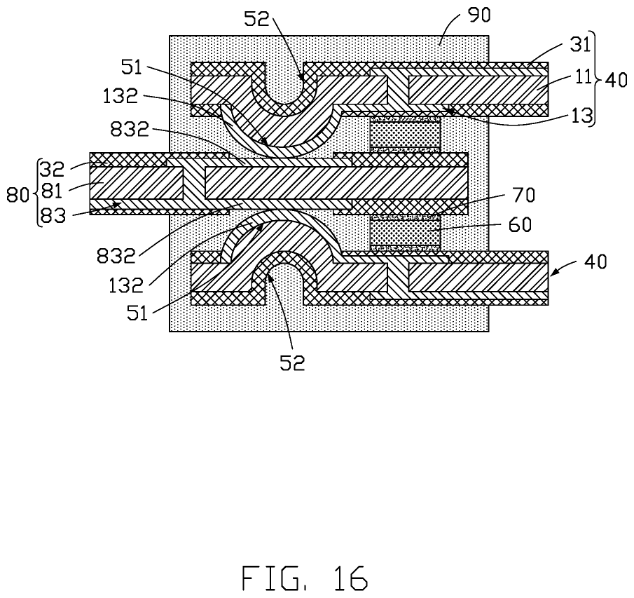

Step S11, referring to FIG. 16, an encapsulation layer 90 encapsulating the first contact pads 132 and the second contact pads 832 is formed, obtaining the circuit board assembly. The encapsulation layer 90 further infills gaps between first circuit boards 40 and the second circuit board 80. The encapsulation layer 90 also acts as a hermetic seal against the air, improving the reliability.

The encapsulation layer 90 further covers a portion of a surface of the first circuit board 40 facing away from the second circuit board 80, a portion of a side face of the first circuit board 40, a portion of a surface of the second circuit board 80 facing away from the first circuit board 40, and a portion of a side face of the second circuit board 80. The encapsulation layer 90 covers corresponding regions of the first circuit board 40 and the second circuit board 80.

The encapsulation layer 90 is made of a non-conductive material. The non-conductive material includes one or more of epoxy molding compound (EMC), acrylonitrile butadiene styrene (ABS), polycarbonate (PC), polyethylene terephthalate (PET), and other injection molding materials.

Referring to FIG. 16, a circuit board assembly according to one embodiment is provided. The circuit board assembly includes two first circuit boards 40 and the second circuit board 80. The first circuit boards 40 are disposed on opposite surfaces of the second circuit board 80.

Each first circuit board 40 includes the first insulating layer 11, two first conductive wiring layers 13 on opposite surface of the first insulating layer 11, and two first protective layers 31 on surfaces of the two first conductive wiring layers 13 facing away from the first insulating layer 11. One first conductive wiring layer 13 of each first circuit board 40 includes the first contact pads 132 which are exposed from the corresponding first protective layer 31.

Each first circuit board 40 defines one slit 41 (shown in FIG. 9) between any two adjacent first contact pads 132. The slit 41 penetrates an end of the first circuit board 40. A portion of the first circuit board 40 having the first contact pads 132 is separated into a plurality of portions through a plurality of slits 41, each of the plurality of portions having one first contact pad 132.

Each first circuit board 40 further includes the first surface 401 and the second surface 402 opposite to the first surface 401. The first surface 401 defines the stamped protrusions 51 corresponding to the first contact pads 132, and each first contact pad 132 is outside a stamped protrusion 51. The second surface 402 defines the stamped grooves 52 having shapes matching the shapes of the stamped protrusions 51.

In other embodiments, the first conductive wiring layer 13 includes only one first contact pad 132, and the second conductive wiring layer 83 includes only one second contact pad 832, and there are only one stamped protrusion 51 being correspondingly positioned relative to a position of the first contact pad 132.

The second circuit board 80 includes the second insulating layer 81, two second conductive wiring layers 83 on opposite surfaces of the second insulating layer 81, and two second protective layers 32 on surfaces of the two second conductive wiring layers 83 facing away from the second insulating layer 81. Each second conductive wiring layer 83 includes the second contact pads 832 which are exposed from the corresponding second protective layer 32.

Each first contact pad 132 of the stamped protrusion 51 of one first circuit board 40 is in contact with a second contact pad 832 of one second conductive wiring layer 83, so that the two first circuit boards 40 are electrically coupled to the second circuit board 80.

In some embodiments, the circuit assembly further includes two supporting blocks 60, one supporting block 60 is sandwiched between one first circuit board 40 and the second circuit board 80, and the other supporting block 60 is sandwiched between the other first circuit board 40 and the second circuit board 80. Each supporting block 60 is adjacent to the stamped protrusions 51 of one first circuit board 40.

In some embodiments, each supporting block 60 is bonded to one first circuit board 40 and the second circuit board 80 by two respective adhesive layers 70.

In some embodiments, the circuit board assembly further includes the encapsulation layer 90. The encapsulation layer 90 infills gaps between the first circuit boards 40 and the second circuit board 80 and encapsulates and seals the first contact pads 132 and the second contact pads 832.

In the circuit board assembly and the manufacturing method, the first contact pads 132 of the first circuit board 40 are in contact with the second contact pads 832 of the second circuit board 80, so that electronic connections between the first circuit board 40 and the second circuit board 80 are achieved. Compared with a hot bar process, neither a solder paste nor a reflow soldering process is required, the process is simplified. Moreover, the encapsulation layer 90 encapsulates the first contact pad 132 and the connected second contact pads 832 to seal against the air, improving the reliability.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A circuit board assembly comprising:
a first circuit board comprising a first insulating layer and a first conductive wiring layer arranged on the first insulating layer, the first conductive wiring layer comprising at least one first contact pad, the first circuit board defining at least one stamped protrusion, the at least one stamped protrusion being correspondingly positioned relative to a position of the first contact pad, the at least one first contact pad being outside the at least one stamped protrusion; and
a second circuit board arranged on the first circuit board, the second circuit board comprising a second insulating layer and a second conductive wiring layer arranged on the second insulating layer, the second conductive wiring layer comprising at least one second contact pad, the at least one second contact pad being in contact with the at least one first contact pad of the at least one stamped protrusion.

2. The circuit board assembly of claim 1, further comprising a supporting block sandwiched between the first circuit board and the second circuit board.

3. The circuit board assembly of claim 2, wherein the supporting block is bonded to the first circuit board and the second circuit board by two respective adhesive layers.

4. The circuit board assembly of claim 1, further comprising an encapsulation layer, the encapsulation layer filling a gap between the first circuit board and the second circuit board and encapsulating the at least one first contact pad and the at least one second contact pad.

5. The circuit board assembly of claim 1, further comprising a first protective layer arranged on a surface of the first conductive wiring layer facing away from the first insulating layer, wherein the at least one first contact pad is exposed from the first protective layer.

6. The circuit board assembly of claim 1, further comprising a second protective layer arranged on a surface of the second conductive wiring layer facing away from the second insulating layer, wherein the at least one second contact pad is exposed from the second protective layer.

7. The circuit board assembly of claim 1, wherein the first conductive wiring layer comprises a plurality of first contact pads, the first circuit board defines a plurality of slits, the plurality of slits separating a portion of the first circuit board having the plurality of first contact pads into a plurality of portions, each of the plurality of portions having one of the plurality of first contact pads; the first circuit board further defines a plurality of stamped protrusions, the plurality of stamped protrusions are correspondingly positioned relative to positions of the plurality of first contact pads, the second conductive wiring layer comprises a plurality of second contact pads, each of the plurality of first contact pads is outside a corresponding stamped protrusion of the plurality of stamped protrusions and is in contact with a corresponding second contact pad of the plurality of second contact pads.

8. A method for manufacturing a circuit board assembly comprising:
providing a first circuit board, the first circuit board comprising a first insulating layer and a first conductive wiring layer, the first conductive wiring layer comprising at least one first contact pad;
stamping the first circuit board to form at least one stamped protrusion so that the at least one stamped protrusion is correspondingly positioned relative to a position of the at least one first contact pad, and the at least one first contact pad is outside the at least one stamped protrusion;
providing a second circuit board, the second circuit board comprising a second insulating layer and a second conductive wiring layer arranged on the second insulating layer, the second conductive wiring layer comprising at least one second contact pad;
pressing the first circuit board onto the second circuit board such that the at least one first contact pad on the at least one stamped protrusion is in contact with the at least one second contact pad.

9. The method of claim 8, before the first circuit board is pressed onto the second circuit board, the method further comprising: forming a supporting block on the first circuit board or on the second circuit board, a height of the at least one stamped protrusion is greater than a height of the supporting block, wherein the supporting block is sandwiched between the first circuit board and the second circuit board when the first circuit board is pressed onto the second circuit board.

10. The method of claim 9, further comprising bonding the supporting block to the first circuit board and the second circuit board by two respective adhesive layers.

11. The method of claim 8, after the first circuit board is pressed onto the second circuit board, the method further comprising: forming an encapsulation layer so that the encapsulation layer fills in a gap between the first circuit board and the second circuit board and encapsulates the at least one first contact pad and the at least one second contact.

12. The method of claim 8, wherein the first conductive wiring layer comprises a plurality of first contact pads, the second conductive wiring layer comprises a plurality of second contact pads, before the first circuit board is stamped, the method further comprises: cutting a portion of the first circuit board between any two adjacent first contact pads to form a slit, the slit penetrating an end of the first circuit board, and a portion of the first circuit board having the plurality of first contact pads is separated into a plurality of portions by a plurality of slits; separated portions of the first circuit board are stamped to form a plurality of stamped protrusions, each of the plurality of first contact pads is outside a corresponding stamped protrusion of the plurality of stamped protrusions, and each of the plurality of first contact pads is in contact with a corresponding second contact pad of the plurality of second contact pads when the first circuit board is pressed onto the second circuit board.

13. The method of claim 8, before the first circuit board is pressed onto the second circuit board, the method further comprising: forming a first protective layer on a surface of the first conductive wiring layer facing away from the first insulating layer, the at least one first contact pad being exposed from the first protective layer.

14. The method of claim 8, before the first circuit board is pressed onto the second circuit board, the method further comprising: forming a second protective layer on a surface of the second conductive wiring layer facing away from the second insulating layer, the at least one second contact pad being exposed from the first protective layer.
